(19) United States
(12) Patent Application Publication
(10) Pub. No.: US 2010/0024729 A1
(43) Pub. Date: Feb. 4, 2010

(54) METHODS AND APPARATUSES FOR UNIFORM PLASMA GENERATION AND UNIFORM THIN FILM DEPOSITION

(76) Inventors: Xinmin Cao, Sylvania, OH (US); Bradley S. Mohring, Delta, OH (US)

Correspondence Address: WILSON, SONSINI, GOODRICH & ROSATI, 650 PAGE MILL ROAD, PALO ALTO, CA, 94304-1050, US

(21) Appl. No.: 12/534,779

(22) Filed: Aug. 3, 2009

Related U.S. Application Data
(60) Provisional application No. 61/086,143, filed on Aug. 4, 2008.

(51) Int. Cl. C23C 16/50; C23C 16/00

(52) U.S. Cl. 118/723 E; 118/723 R

(57) ABSTRACT

System for depositing a thin film over a substrate comprise a reaction space, a substrate support member configured to permit movement of a substrate in a longitudinal direction, and a plasma-generating apparatus disposed in the reaction space and configured to form plasma-excited species of a vapor phase chemical. The plasma-generating apparatus can comprise a cathode unit having an electrode plate and one or more gas diffuser plates for forming a high-density, linearly-shaped and uniform plasma in a space between the substrate and the cathode unit.

The application claims the benefit of U.S. Provisional Patent Application No. 61/086,143, filed Aug. 4, 2008, which is entirely incorporated herein by reference.

### FIELD OF THE INVENTION

The invention relates to improved thin film deposition methods and apparatuses for producing large-area semiconductor thin films. More particularly, the invention relates to systems and methods that employ a large-area cathode assembly and plasma-enhanced chemical vapor deposition (PECVD) for generating uniform high-density plasma to produce high-quality and uniform large-area semiconductor thin films.

### BACKGROUND OF THE INVENTION

Plasma-enhanced chemical vapor deposition (PECVD) is based on electron impact dissociation of a gas (or vapor), such as a gas comprising plasma-excited species of silane (SiH₄) and hydrogen (H₂). Conventional PECVD systems for making silicon thin films utilize capacitively-coupled plasma glow discharge reactors. In these systems, an AC electrical field with a standard radio frequency (RF) of 13.56 MHz is introduced between a capacitively-coupled planar cathode and anode. When process gases flow through the electrical field, plasma-excited species of the process gases comprising radicals, electrons, ions, and atoms are generated. RF plasma gives a negative self-bias to substrates and electrodes, because light, fast electrons are more mobile to RF frequencies than the heavier ions and can build up negative charges on substrates and electrodes. Because the substrate and electrodes are slightly negative with respect to the weakly ionized bulk plasma, negative ions are trapped in the bulk plasma, while the neutral radicals and positive ions can reach the substrate by diffusion and drift motion, respectively. The radicals and (quickly neutralized) ions adsorb on the substrate and grow a thin film through complex reactions via several steps, such as a reaction between vapor phase radicals and an exposed surface of the substrate or thin film, as well as subsurface diffusion of radicals.

Current manufacturing or industrial-scale processes for forming or depositing semiconductor layers of thin-film silicon (tf-Si) for use in photovoltaic (PV) modules use RF PECVD, a method that deposits tf-Si materials at relatively low deposition rates (e.g., about 2 Å/s). Such low rates require large machine sizes and lead to high manufacturing costs.

PECVD at very high frequency (VHF), with a frequency in the range of 15 MHz to 300 MHz has been explored as an alternative to RF based PECVD, but it is limited—for electronic quality material—to rates below about 30 Å/s, much higher than RF plasma excitation but lower than hot wire (HW) excitation. However, VHF PECVD is not used widely in current large-area thin film production due to the problem of plasma non-uniformity mainly caused by standing wave effect. Hence, homogeneous growth of silicon based thin films over a large area becomes a major challenge.

By employing a combination of a high deposition pressure (e.g., greater than about 2 Torr) and silane depletion in a conventional RF PECVD deposition system, in a regime called high-pressure depletion (HPD), ion bombardment can be suppressed under high-pressure conditions and the density of atomic hydrogen can be increased under depletion conditions, which leads to high quality thin film silicon material growth at high rates. However, under the high deposition pressure conditions, a small substrate-cathode spacing (e.g., less than about 30 mm) is generally required for a deposition rate greater than about 5 Å/s. For large-area thin-film silicon deposition using large-area cathode engineering, the non-uniformity in substrate-cathode spacing over the large-area cathode surface, which is mainly caused by the flatness and parallel of substrate and cathode surface, would also affect the plasma non-uniformity in the large-area discharge space and, consequently, the thickness non-uniformity in the deposited thin films.

### SUMMARY OF THE INVENTION

In one aspect of the invention, a system for forming a thin film over a substrate comprises a reaction space (or process chamber), a substrate support member configured to permit movement of a substrate in a longitudinal direction, and a plasma-generating apparatus disposed in the reaction space and configured to form plasma-excited species of a vapor phase chemical. In a preferable embodiment, the plasma-generating apparatus is configured to form plasma-excited species of a vapor phase chemical in the reaction space.

In another aspect of the invention, a system for forming a thin film over a substrate, comprises a process chamber, a substrate support member configured to permit movement of a substrate through the process chamber, and a plasma-generating apparatus disposed in the process chamber. In an embodiment, the plasma-generating apparatus includes a cathode unit comprising one or more gas diffuser members and an electrically conductive member. In an embodiment, the electrically conductive member comprises at least one electrical power feedthrough and an electrode plate. In a preferable embodiment, plasma-excited species of a vapor phase chemical are generated between the electrode plate and a substrate in the process chamber.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The features and advantages of the invention can be further explained by reference to the following detailed description and accompanying drawings that sets forth illustrative embodiments of the invention.

FIG. 1 is a schematic cross-sectional side view of a roll-to-roll thin-film deposition system, in accordance with an embodiment of the invention;

FIG. 2 is cross-sectional side view of a shower head, in accordance with an embodiment of the invention;

FIG. 3 is a top-down view of a cathode in the roll-to-roll thin-film deposition system, in accordance with an embodiment of the invention;

FIG. 4 is a detailed view of a smaller section of the cathode, in accordance with an embodiment of the invention;

FIG. 5 is a schematic cross-sectional side view of an apparatus comprising a large-area cathode unit having an electrode plate with a linearly-grooved hollow cathode array, and a shower head configuration with two gas diffuser plates; and

FIG. 6 is a detailed cross-sectional view of a portion of the cathode unit with shielding and chamber walls, in accordance with an embodiment of the invention.

### DETAILED DESCRIPTION OF THE INVENTION

The invention provides methods and apparatuses for depositing semiconductor-containing thin films. More particularly, the invention relates to systems and methods that employ an improved large-area cathode assembly and plasma-enhanced chemical vapor deposition (PECVD) for generating uniform high-density plasma, and for producing high-quality large-area semiconductor thin films of high uniformity at high deposition rates. Such systems can include one or more reaction spaces, each reaction space having one or more plasma-generating apparatuses configured for PECVD using DC, pulse DC, Medium Frequency, RF, VHF or other AC power supplies or combination thereof, such as dual frequency. A substrate on which deposition is desired can be moved through a reaction space at a predetermined rate during thin films deposition.

An aspect of the invention provides a system for depositing a thin film over a substrate. The system comprises a reaction space, a substrate support member configured to permit movement of a substrate in a longitudinal direction, and a plasma-generating apparatus disposed in the reaction space and configured to form plasma-excited species of a vapor phase chemical or gas. The system further comprises a cathode unit disposed in the reaction space and configured to decompose vapor phase chemicals. The cathode unit can be a combination of a shower head and an electrical (or electrically) conductive member that has a planar and flat electrode plate at the top of the electrically conductive box and facing the substrate, where a plasma discharge can be generated. In an embodiment, plasma is generated between the electrically conductive box and the substrate. In an embodiment, the electrically conductive member is an electrically conductive box.

In one embodiment of the invention, the cathode unit further comprises an electrode plate machined with an array of a plurality of hollow cathode cells, which generates a corresponding distribution of plasma array in the plasma space between the substrate and the cathode surface. Each hollow-cathode cell is defined by a wall or a plurality of walls that can be of any size and shape, such as circular dotted hole, quadrilateral hole, hexagonal hole, or hollow grooved line. In an embodiment, a hollow grooved line has the topology of a trench machined into the cathode unit. The distribution of hollow cathode cells, the size of each hollow cathode cell and the shape of each hollow cathode cell can be adjusted to compensate a plasma non-uniformity caused by, for example, a standing wave effect under a large-area VHF PECVD condition, or by the waviness of a stainless steel or polymer substrate web under a roll-to-roll thin-film manufacturing situation.

In one embodiment of the invention, the cathode unit further comprises an electrode plate having a plurality of linearly grooved hollow cathode patterns on a discharge electrode plate surface of the cathode unit, which generates high-density linearly-shaped uniform plasma array in the plasma space between the substrate and the cathode surface.

The shower head apparatus can further comprise one or more gas diffuser members (or plates) inside the shower head box, which provides uniform gas distribution in the plasma space over the cathode surface.

The thin film deposition chamber further comprises a substrate support member configured to permit movement of a substrate in a longitudinal direction. The substrate support member can also maintain the substrate in a steady, horizontal plain relative to an electrode plate over the substrate.

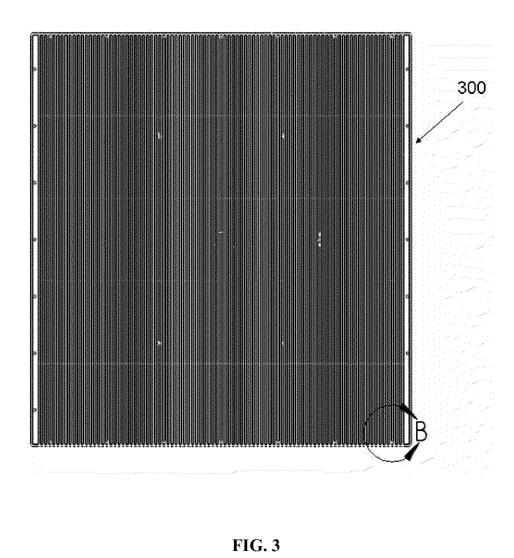

Another embodiment of the invention provides a thin film deposition chamber comprising a substrate support member configured to permit movement a substrate in a longitudinal direction, and a cathode unit that has an electrode plate having a plurality of linearly grooved hollow cathode patterns, wherein the longitudinal direction of the linearly grooved hollow cathode is parallel to the electrode plate surface and preferably perpendicular to substrate moving direction (see FIG. 3).

Another aspect of the invention provides methods for depositing one or more layers of a semiconductor-containing material on a substrate. A preferable method comprises providing the substrate in a plasma reaction space. Next, a process gas (or vapor phase chemical) is provided in the reaction space through a shower head, the gas including a semiconductor-containing chemical. Plasma-excited species of the semiconductor-containing chemical are formed in the reaction space. The substrate is contacted with the plasma-excited species of the semiconductor-containing chemical. In a preferable embodiment of the invention, the substrate is contacted with the plasma-excited species while it is moved from a first position to a second position in the reaction space.

Reference will now be made to the figures, wherein like numerals or designations refer to like parts throughout. It will be appreciated that the figures are not necessarily drawn to scale.

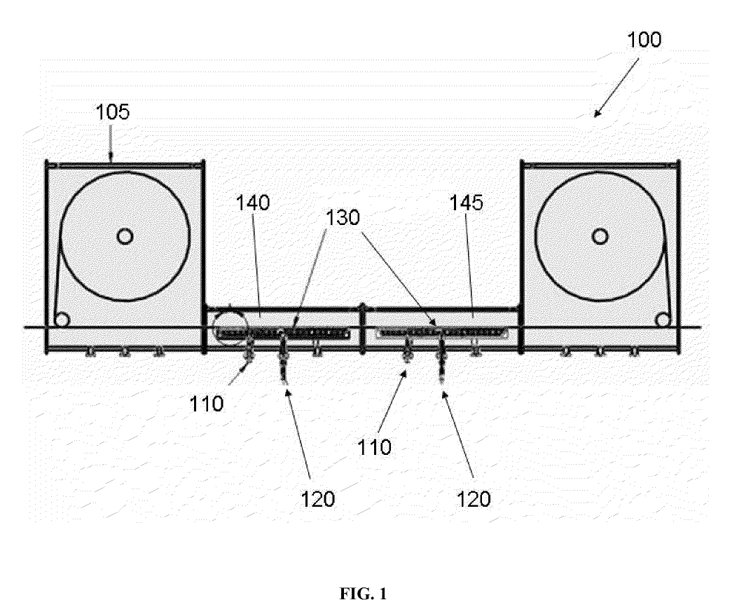

FIGS. 1-4 show a roll-to-roll thin film deposition system and a cathode unit of various embodiments of the invention.

With reference to FIG. 1, a thin-film deposition system 100 is shown having a roll-to-roll system 105, two gas feedthrough members 110, two power feedthrough members 120, and two cathode units (also “cathode members” herein) 130. In an embodiment, the roll-to-roll system 105 comprises a pay-out (left chamber) and take-up (fight chamber) chambers. In an embodiment, the cathode units (or plasma generating apparatuses) 130 are disposed in separate reaction spaces (or process chambers). In the illustrated embodiment, a first reaction space 140 is disposed adjacent a second reaction space 145. The roll-to-roll system 105 comprises a substrate support member, such as a substrate web, that comprises a substrate over which one or more vapor phase chemicals are to be deposited. Each reaction space 140, 145 can be configured to provide plasma-excited species of one or more vapor phase chemicals. In an embodiment, the one or more vapor phase chemicals in the first reaction space 140 are different than the one or more vapor phase chemicals in the second reaction space 145. In another embodiment, the one or more vapor phase chemicals are the same. In an embodiment, each of the cathode units 130 is configured to provide one or more vapor phase chemicals into each of the reaction spaces 140, 145.

With continued reference to FIG. 1, while two reaction spaces and two cathode units have been illustrated, it will be appreciated that the thin film deposition system 100 of FIG. 1 can comprise any number of reaction spaces and cathode units. For example, the thin film deposition system 100 can comprise 1, 3, 4, 5, 6, 7, 8, 9, or 10 cathode units in separate reaction spaces. In some cases, one reaction space can include multiple cathode units. For example, one reaction space can comprise 2, 3, 4, 5, 6, 7, or 8 cathode units.

With continued reference to FIG. 1, the thin film deposition system 100 can include one or more heating elements (not shown) configured to heat the substrate during vapor phase deposition. In an embodiment, the one or more heating elements are disposed proximate the substrate on a side of the substrate opposite the cathode units 130.

With reference to FIG. 1, the thin film deposition system 100 can include a vacuum system (not shown) for providing a vacuum in one or more of the reaction spaces 140, 145. The vacuum system can include one or more pumps, such as a mechanical pump and a turbomolecular (“turbo”) pump. In an embodiment, the think film deposition system 100 comprises a computer system for controlling various process elements of the system, such as pressure, substrate temperature, dosing of one or more vapor phase chemicals, introduction of a purge gas, and the velocity with which the substrate support member moves a substrate through the reaction spaces 140, 145.

In an embodiment, the power feedthrough members 120 are in electrical contact with a power supply. In an embodiment, the power feedthrough members 120 electrically coupled the cathode units 130 to a pulsed power supply, medium frequency power supply, a dual frequency power supply, a radiofrequency (RF) power supply, a very high frequency (VHF) power supply, or a direct current (DC) power supply.

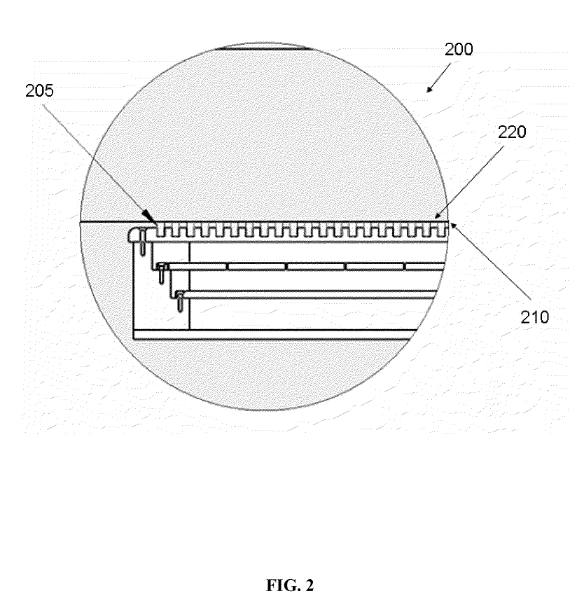

FIG. 2 is cross-sectional side view of a cathode unit 200 of embodiments of the invention, showing a plasma discharge area (or plasma space) 205 for forming plasma-excited species of a vapor phase chemical. In the illustrated embodiment, the plasma space is disposed between a top surface (or plate) 210 of the cathode unit 200 and a substrate 220. In an embodiment, the substrate 220 is provided with the aid of a substrate support member, such as a roll-to-roll system. In a preferable embodiment, the cathode unit 200 has a showerhead (also “shower head” herein) configuration.

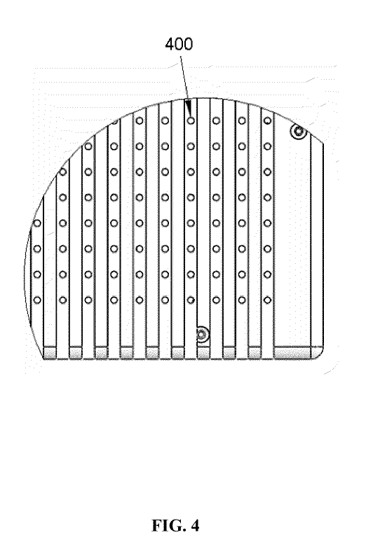

FIG. 3 is a top-down view of the cathode unit of various embodiments of the invention, showing a top surface of the cathode unit. In an embodiment, the cathode unit comprises a linearly grooved hollow cathode array 300 having gas feedthrough holes (see FIG. 4) oriented along a direction generally parallel to the direction of movement of a substrate support member—i.e., the holes are generally oriented along a direction that is parallel to a velocity vector of the substrate support member.

With reference to FIG. 4, a portion of a surface of the cathode unit of embodiments of the invention is illustrated. The surface comprises a linear grooved (also “linearly-grooved” herein) hollow cathode array with gas feed (or feedthrough) holes 400.

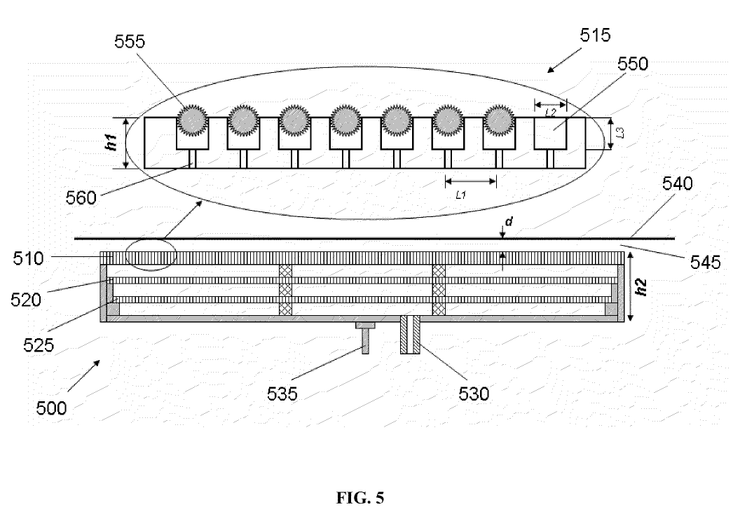

FIG. 5 is a schematic cross-sectional side view of an apparatus comprising a large-area cathode unit 500 having an electrode plate 510 comprising a linearly-grooved hollow cathode array 515. The cathode unit 500 of the illustrated embodiment has a shower head configuration with two gas diffuser plates, a first gas diffuser plate 520 and a second diffuser plate 525. The cathode unit further comprises a gas feedthrough member 530 and an electrical feedthrough member 535 for providing power to the cathode unit 500. Power may be provided by a power supply. In an embodiment, the cathode unit 500 is electrically coupled to a pulsed power supply, medium frequency power supply, a dual frequency power supply, a radiofrequency (RF) power supply, a very high frequency (VHF) power supply, or a direct current (DC) power supply.

With continued reference to FIG. 5, the cathode unit 500 is disposed adjacent a substrate support member 540. The substrate support member 540 comprises a substrate. In an embodiment, the cathode unit 500 is disposed in a reaction space, and as the substrate support member 540 passes through the reaction space plasma-excited species of a vapor phase chemical are generated in a plasma space 545 and brought in contact with a top surface of a substrate. In an embodiment, the substrate support member 540 comprises a substrate web. The substrate support member 540 can be part of a roll-to-roll deposition system (see FIG. 1). The distance, ‘d’, between a top surface of the cathode unit 500 and a surface of the substrate on the substrate support member 540 can be adjusted to provide a plasma discharge as desired.

In an embodiment, the substrate support member 540 serves as the anode and the cathode unit 500 serves as the cathode. In such a case, the substrate support member 540 can be grounded and the cathode unit 500 can be in electrical communication with a power supply (not shown).

With continued reference to FIG. 5, the electrode plate (or member) 510 of the cathode unit 500 comprises a linearly grooved hollow-cathode array 515 (which are made up of individual hollow-cathodes 550) for generating a confined linear plasma 555 (also “confined linear plasma array” herein) in the plasma space 545. The electrode plate 510 further comprises a drill-through hole array 560 (this array 560 produces a “showerhead” for gas distribution).

With reference to FIGS. 1-6, the system (also “deposition system” herein) may comprise a chamber having a large-area cathode unit, which includes an electrode plate with a plurality of linearly grooved hollow cathode, and a shower head configuration with two gas diffuser plates. A substrate web (e.g., a stainless steel web) moves through the chamber at a distance up to about 50 mm away from, and parallel to, the electrode plate disposed above the substrate. The substrate web could be in electrical communication with ground (or “grounded”). The substrate can heated by a “heater” positioned parallel to it (not shown in FIGS. 1 and 2). The heater can be disposed below the substrate and away form the electrode plate. An electrical (or power) feedthrough and a process gas feedthrough are connected to the cathode unit at the bottom of the cathode unit. Regularly or uniformly-distributed drill-through hole arrays on the top electrode plate as well as on the two gas diffuser plates provide uniform process gas distribution in the plasma space over the cathode surface. VHF, RF or DC plasma can be excited between the substrate and the cathode surface. With proper control of deposition parameters, a high-density, linearly-shaped and uniform plasma can be generated in the plasma space between the substrate and the cathode surface. With the substrate web moving in a longitudinal direction at a certain speed, high-quality large-area semiconductor thin films can be produced with high uniformity and at a high deposition rate.

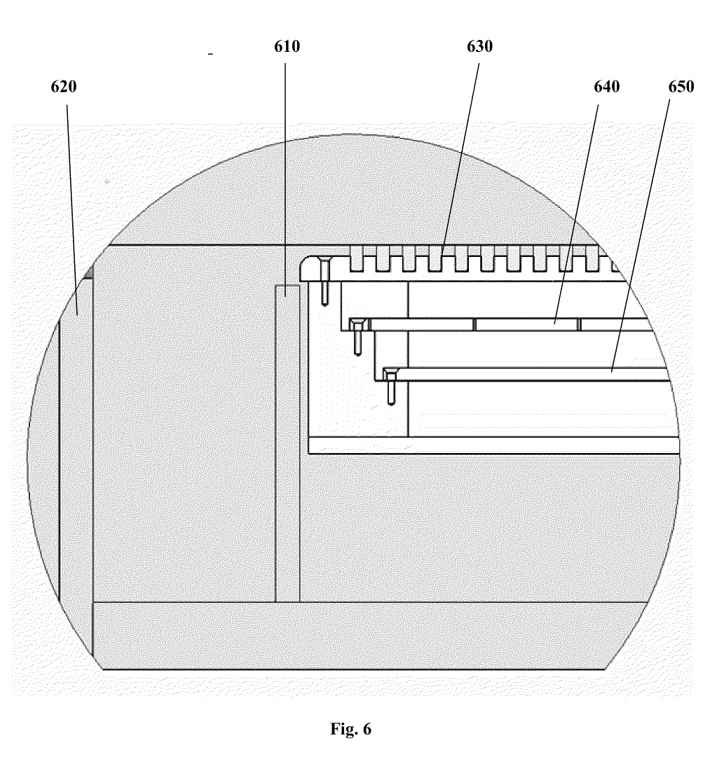

With reference to FIG. 5, the cathode unit 500 can be of any shape, such as a cubic box. In such a case, the cathode unit can have a height (‘h2’ of FIG. 5) between about 10 mm and about 1000 mm, or between about 20 mm and about 200 mm; a length between about 10 mm and about 4000 mm, or between about 200 mm and about 2000 mm; and a width between about 10 mm and about 4000 mm, or between about 200 mm and about 2000 mm. The cathode unit can comprise electrically grounded shield plates (see e.g., FIG. 6) or chamber walls that are disposed around the cathode unit (see e.g., FIG. 6), wherein the spacing between a shield plate or chamber wall and an opposing surface of the cathode box is between about 0.2 mm and about 200 mm, or between about 2 mm and about 80 mm.

With reference to FIG. 6, electrically grounded shield plates 610 and chamber wall 620 may be disposed around the cathode and can be comprised as part of the cathode unit. In some instances, the chamber wall 620 may be some predetermined distance from an electrically grounded shield plate 610. For example, the predetermined distance between the chamber wall and grounded shield plate may fall within 0.2 mm to 200 mm. The cathode unit may also include an electrode plate 630, a first gas diffuser plate 640 and/or a second gas diffuser plate 650, which may have any of the characteristics or features described herein.

A gas diffuser plate (also “gas diffuser” herein) of the cathode unit 500 can comprise a plurality of gas feed (or feedthrough) holes, wherein each hole has a diameter of about 0.1-20 mm, or about 0.5-3 mm. The spacing between two nearest holes of the gas diffuser can be in the range of about 0.2-200 mm, or about 20-80 mm; a thickness of the gas diffuser plate in the range of 1-40 mm, more specifically, 3-15 mm. A length of the gas diffuser plate can be in the range of about 10-4000 mm, or about 200-2000 mm. A width of the gas diffuser plate can be in the range of about 10-4000 mm, or about 200-2000 mm.

The shower head configuration of the cathode unit can comprise at least one process gas feedthrough tube that is disposed at any location, such as at or near the center of the bottom of the shower head box or electrical box (see, e.g., gas feedthrough member 530 of FIG. 5). The shower head configuration further comprises one or more gas diffuser plates, which can provide uniform gas distribution in the plasma space over the cathode surface.

With reference to FIG. 5, the cathode unit 500 can be a least partially defined by an electrically-conductive box. At least one electrical power feedthrough can be connected to the electrically-conductive box at any location, such as at or near the center of the bottom of the cathode unit (see, e.g., electrical power feedthrough 535 of FIG. 5). The cathode unit can further comprise a planar and flat electrode plate on the top of the cathode unit and facing the substrate, wherein a plasma discharge (or plasma-excited species) can be generated in-between.

The cathode unit can further comprise an electrode plate placed on the top of the cathode unit and facing the substrate. In an embodiment, the substrate is provided to a reaction space with the aid of a substrate support member, such as a roll-to-roll substrate support member (see FIG. 1). The cathode unit can comprise an array of a plurality of hollow cathode cells, which generate a corresponding distribution of plasma array in the plasma space between the substrate and the cathode surface. The electrode plate can comprise a plurality of gas feed (or feed through) holes, wherein each hole has a diameter (‘L2’ of FIG. 5) of about 0.1-20 mm, or about 0.5-3 mm, and wherein the spacing between two nearest holes (‘L1’ of FIG. 5) is in the range of about 0.2-200 mm, or about 20-80 mm. The electrode plate can have a thickness (‘h1’ of FIG. 5) in the range of about 1-40 mm, or about 5-25 mm; a length in the range of about 10-4000 mm, or about 200-2000 mm; and a width in the range of about 10-4000 mm, or about 200-2000 mm.

The hollow cathode cell can be defined by a wall or walls that can be of any shape, such as circular dotted hole, quadrilateral hole, hexagonal hole, or hollow grooved line, which can also be of any size. The size of each hollow cathode cell and the shape of each hollow cathode cell can be adjusted to compensate a plasma non-uniformity caused, for example, by a standing wave effect under a large-area VHF PECVD condition, or by a waviness of a stainless steel or polymer substrate web under a roll-to-roll thin-film manufacturing situation.

The electrode plate can comprise a plurality of linearly-grooved hollow cathode patterns on the discharge electrode plate surface of the cathode unit, which generates a high-density, linearly-shaped and uniform plasma array in the plasma space between the substrate and a cathode surface, such as a surface of the electrode plate. The plurality of the linearly grooved hollow cathodes can have a width of about 1-100 mm, or about 3-20 mm; a depth (‘L3’ of FIG. 5) of about 1-100 mm, or about 3-20 mm; a length of about 10-4000 mm, or about 200-2000 mm. The longitudinal direction of the linearly grooved hollow cathode is parallel to the electrode plate surface, and the angle between the longitudinal direction of the linearly grooved hollow cathode and the substrate web moving direction is in the range of 0-180 degrees. In a preferable embodiment of the invention, the angle between the longitudinal direction of the linearly grooved hollow cathode and the substrate web moving direction is about 90 degrees.

With reference to FIG. 5, one or more of the electrode plate 510 and the two gas diffusers (or gas diffuser plates) 520 and 525 can be in electrical communication (or electrical contact) with a power supply (e.g., RF power supply, VHF power supply). For example, the electrode plate 510 can be in electrical communication with a power supply and the two gas diffusers 520 and 525 can be insulated (or shielded) from the power supply. As another example, the electrode plate 510 and the first (or top) gas diffuser 520 can be in electrical communication with the power supply and the second (or bottom) gas diffuser 525 can be insulated from the power supply. As still another example, the electrode plate 510 and the two gas diffusers 520 and 525 can all be in electrical communication with the power supply.

With continued reference to FIG. 5, while the cathode unit 500 includes a top electrode plate 510 and two gas diffuser plates 520 and 525, the cathode unit 500 can include any number of gas diffuser plates. For example, the cathode unit 500 can include 1, 2, 3, 4, 5, 6, 7, 8, 9, or 10 gas diffuser plates. Additionally, it will be appreciated that while the cathode unit 500, as illustrated, comprises an electrode plate 510 that is in electrical communication with a power supply (via electrical feedthrough member 535), in some cases the cathode unit 500 (or electrode plate 510 of the cathode unit 500) could be grounded and the substrate (or substrate web 540) could be in electrical communication with the power supply. In such a case, the apparatus of FIG. 5 could serve as the anode.

### Example 1

A system having a reactor, like the reactor of FIG. 1, and a cathode unit, like the cathode unit of FIG. 5, is provided. The cathode unit has a discharge surface area of about 100 cm by 100 cm and a height of about 10 cm. Each linearly grooved hollow cathode has a dimension of about 5 mm by 6 mm by 100 mm. The substrate is a stainless steel web having dimensions of about 0.127 mm by 915 mm. The substrate moves at a speed of about 25 cm per minute through a process chamber (or reaction space) of the reactor. The process gas includes a mixture of silane and hydrogen in a ratio of about 1:10 and the process pressure is in the range of about 0.2 Torr-10 Torr. The spacing between the substrate and the cathode surface is about 20 mm. The process pressure in the reactor, as well as the VHF power applied to the cathode is, adjusted so that a linear plasma can be uniformly generated in the each linearly grooved hollow-cathode between the substrate and the cathode. A silicon film with a thickness of about 480 nm can be produced with a low non-uniformity of less than or equal to about ±5% on the stainless steel substrate support web with a high deposition rate of about 20 Å/s.

For each aspect of the invention, many variations are possible as suggested herein that are known to those of ordinary skill in the art. A variety of changes and modifications can be made within the scope of the invention without departing from the spirit thereof.

It should be understood from the foregoing that, while particular implementations have been illustrated and described, various modifications can be made thereto and are contemplated herein. It is also not intended that the invention be limited by the specific examples provided within the specification. While the invention has been described with reference to the aforementioned specification, the descriptions and illustrations of embodiments of the invention herein are not meant to be construed in a limiting sense. Furthermore, it shall be understood that all aspects of the invention are not limited to the specific depictions, configurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents.

What is claimed is:

1. A roll-to-roll system for forming a thin film over a substrate, comprising:
a reaction space;
a substrate support member configured to permit movement of the substrate in a longitudinal direction; and
a plasma-generating apparatus disposed in the reaction space and configured to form plasma-excited species of a vapor phase chemical.

2. The roll-to-roll system of claim 1, wherein the plasma-generating apparatus is electrically isolated from one or more walls of the reaction space.

3. The roll-to-roll system of claim 1, wherein the plasma-generating apparatus is configured to provide the vapor phase chemical into the reaction space.

4. The roll-to-roll system of claim 1, further comprising one or more heating elements configured to heat the substrate during vapor phase deposition.

5. The roll-to-roll system of claim 4, wherein the one or more heating elements are disposed proximate the substrate on a side of the substrate opposite the plasma-generating apparatus.

6. The roll-to-roll system of claim 1, wherein the plasma-generating apparatus is electrically coupled to a pulsed power supply, medium frequency power supply, a dual frequency power supply, a radiofrequency (RF) power supply, a very high frequency (VHF) power supply, or a direct current (DC) power supply.

7. The roll-to-roll system of claim 1, wherein the substrate support member is configured to permit movement of a the substrate in a longitudinal direction during thin film deposition.

8. The roll-to-roll system of claim 1, wherein the plasma-generating apparatus comprises a cathode unit for generating plasma, wherein the cathode unit comprises an electrically conductive member.

9. The roll-to-roll system of claim 8, wherein the cathode unit is in the shape of a box having a height between about 10 mm and 1000 mm, a length between about 10 mm and 4000 mm, and a width between about 10 mm and 4000 mm.

10. The roll-to-roll system of claim 8, wherein the cathode unit comprises a gas diffuser plate having a plurality of gas feed holes, wherein each hole of the plurality of gas feed holes has a diameter between about 0.1 mm and 20 mm, and a spacing between two nearest holes of between about 0.2 mm and 200 mm.

11. The roll-to-roll system of claim 10, wherein the gas diffuser plate has a thickness between about 1 mm and 40 mm.

12. The roll-to-roll system of claim 10, wherein the gas diffuser plate has a length between about 10 mm and 4000 mm.

13. The roll-to-roll system of claim 10, wherein the gas diffuser plate has a width between about 10 mm and 4000 mm.

14. The roll-to-roll system of claim 8, wherein the cathode unit comprises:
at least one process gas feedthrough tube; and
one or more gas diffuser plates inside the electrically conductive member, wherein the one or more gas diffuser plates are configured to provide uniform gas distribution in a plasma space over the cathode unit.

15. The roll-to-roll system of claim 8, wherein the electrically conductive member of the cathode unit comprises:
at least one electrical power feedthrough; and
an electrode plate disposed at the top of the electrically conductive member and facing the substrate, wherein plasma is generated between the electrode plate and the substrate.

16. The roll-to-roll system of claim 8, wherein the cathode unit comprises an electrode plate disposed at the top of the electrically conductive member and facing the substrate, the electrode plate comprising a plurality of hollow cathode cells that are configured to generate a plasma in a plasma space between the substrate and the cathode unit.

17. The roll-to-roll system of claim 16, wherein the electrode plate further comprises a plurality of gas feed holes, wherein each hole of the plurality of gas feed holes has a diameter between about 0.1 mm and 20 mm.

18. The roll-to-roll system of claim 17, wherein a spacing between two nearest holes is between about 0.2 mm and 200 mm.

19. The roll-to-roll system of claim 16, wherein the electrode plate has a thickness that is between about 1 mm and 40 mm.

20. The roll-to-roll system of claim 16, wherein the electrode plate has a length that is between about 10 mm and 4000 mm.

21. The roll-to-roll system of claim 16, wherein the electrode plate has a width that is between about 10 mm and 4000 mm.

22. The roll-to-roll system of claim 16, wherein the electrode plate comprises a plurality of linearly-grooved hollow cathode patterns on a surface of the electrode plate.

23. The roll-to-roll system of claim 22, wherein the linearly-grooved hollow cathode patterns have a width that is between about 1 mm and 100 mm, a depth that is between about 1 mm and 100 mm, and a length that is between about 10 mm and 4000 mm.

24. The roll-to-roll system of claim 22, wherein a longitudinal direction of the linearly grooved hollow cathode patterns is parallel to a surface of the electrode plate.

25. A system for forming a thin film over a substrate, comprising:
a process chamber;
a substrate support member configured to permit movement of a substrate through the process chamber; and
a plasma-generating apparatus disposed in the process chamber, the plasma-generating apparatus having a cathode unit comprising:
one or more gas diffuser members; and
an electrically conductive member comprising at least one electrical power feedthrough and an electrode plate, wherein plasma-excited species of a vapor phase chemical are generated between the electrode plate and a substrate in the process chamber.

26. The system of claim 25, wherein the electrode plate comprises a plurality of hollow cathode cells that are configured to generate plasma-excited species of a vapor phase chemical in a plasma space between the cathode unit and a substrate in the process chamber.

27. The system of claim 26, wherein the electrode plate further comprises a plurality of gas feed holes.

28. The system of claim 27, wherein each of the plurality of gas feed holes has a diameter between about 0.1 mm and 20 mm.
